(19) United States
(12) Patent Application Publication
(10) Pub. No.: US 2017/0084594 A1
(43) Pub. Date: Mar. 23, 2017

(54) EMBEDDING DIE TECHNOLOGY

(71) Applicant: QUALCOMM Incorporated, San Diego, CA (US)

(72) Inventors: Jongchil NA, San Diego, CA (US); Hong Bok WE, San Diego, CA (US); Ruey Kae ZANG, San Diego, CA (US)

(21) Appl. No.: 14/859,321

(22) Filed: Sep. 20, 2015

(51) Int. Cl. H01L 25/00; H01L 21/56; H01L 25/065

(52) U.S. Cl. CPC H01L 25/50; H01L 25/0657; H01L 21/563; H01L 2225/06513; H01L 2225/06548

(57) ABSTRACT

A die can be mounted on an already made pattern. Thereafter, substrate and other metal layers can be provided so as to embed the die in the substrate. This avoids the need to form a cavity in the substrate for die placement prevalent in conventional die embedding processes. As a result, die embedding process can be simplified. Also, die misalignment can be reduced or eliminated.

### FIELD OF DISCLOSURE

The field of the disclosed subject matter generally relates to semiconductor devices and to methods of manufacturing the semiconductor devices. In particular, the field of the disclosed subject matter relates to embedding of one or more dies in a substrate of a semiconductor device.

### BACKGROUND

In a conventional die embedding process, a cavity is first made in a dielectric. Then a die is inserted in the cavity. This is followed by laminating the dielectric and the metal layer. However, the conventional process requires more processes and materials like cavity forming, attaching film for die placement, and detaching the film. Also, it has die dislocation problems. Further, the die and the metal layer can be misaligned.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

An exemplary semiconductor device is disclosed. The semiconductor device may comprise a substrate, a first die, first die bumps, first joints and patterned contacts. The first die may be embedded in the substrate. The first die bumps may be coupled to the first die, and the first joints may be coupled to the first die bumps. The patterned contacts may be coupled to the first joints such that the first die is electrically coupled to the patterned contacts through the first die bumps and the first joints. The patterned contacts may be at or below a height of the substrate.

An exemplary method of manufacturing a semiconductor device is disclosed. The method may comprise forming a first die. The method may also comprise forming first die bumps and coupling the first die bumps to the first die. The method may further comprise forming first joints and coupling the first joints to the first die bumps. The method may further comprise forming patterned contacts and coupling the patterned contacts to the first joints such that the first die is electrically coupled to the patterned contacts through the first die bumps and the first joints. The method may further comprise providing a substrate such that the first die is embedded in the substrate and such that the patterned contacts are at or below a height of the substrate.

Another exemplary method of manufacturing a semiconductor device is disclosed. The method may comprise forming a carrier. The method may also comprise forming a first die assembly on the carrier. The method may further comprise separating the first die assembly from the carrier. The process of forming the first die assembly may comprise forming patterned contacts on the carrier. The process may also comprise forming a first die. The process may further comprise forming first die bumps and coupling the first die bumps to the first die. The process may further comprise forming first joints and coupling the first joints to the first die bumps and to the patterned contacts such that the first die is electrically coupled to the patterned contacts through the first die bumps and the first joints. The process may further comprise providing a substrate such that the first die is embedded in the substrate and such that the patterned contacts are at or below a height of the substrate.

### BRIEF DESCRIPTION OF THE DRAWINGS

The accompanying drawings are presented to aid in the description of embodiments of one or more aspects of the disclosed subject matter and are provided solely for illustration of the embodiments and not limitation thereof.

FIG. 1A illustrates an example embodiment of a semiconductor device;

FIG. 1B illustrates another example embodiment of a semiconductor device;

FIGS. 2A and 2B illustrate examples of different stages of forming a semiconductor device;

FIGS. 2C-2F illustrate examples of different stages of forming a semiconductor device of FIG. 1A;

FIGS. 2G-2J illustrate examples of different stages of forming a semiconductor device of FIG. 1B;

FIG. 3 illustrates a flow chart of an example method of forming a semiconductor device;

FIG. 4 illustrates a flow chart of another example method of forming a semiconductor device;

FIG. 5 illustrates a flow chart of an example process of forming a die assembly; and

FIG. 6 illustrates examples of devices with a die assembly integrated therein.

### DETAILED DESCRIPTION

Aspects of the subject matter are provided in the following description and related drawings directed to specific embodiments of the disclosed subject matter. Alternate embodiments may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular embodiments only and is not intended to be limiting of embodiments of the disclosed subject matter. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

As indicated above, conventional die embedding processes typically include making a cavity in a dielectric, inserting the die into the cavity, followed by laminating the dielectric and the metal layer. Also as indicated above, such conventional die embedding processes can cause the die to dislocate and/or the metal layer to be misaligned.

However, in an aspect, it is proposed to mount a die on an already made circuit pattern.

This can be accomplished through a die attaching process such as mass reflow or thermal compression bonding. Thereafter, substrate (e.g., dielectric) and other metal layers can be laminated. This has at least the following advantages. First, there is no need to form a cavity for die placement. Thus, activities such as cavity forming, tape laminating to place and hold the die in cavity, and tape detaching typical of the conventional process are no longer required. Second, the die dislocation and misalignment between the die and metal pattern associated with the conventional process can be prevented. Third, finer pitch bump connections are possible.

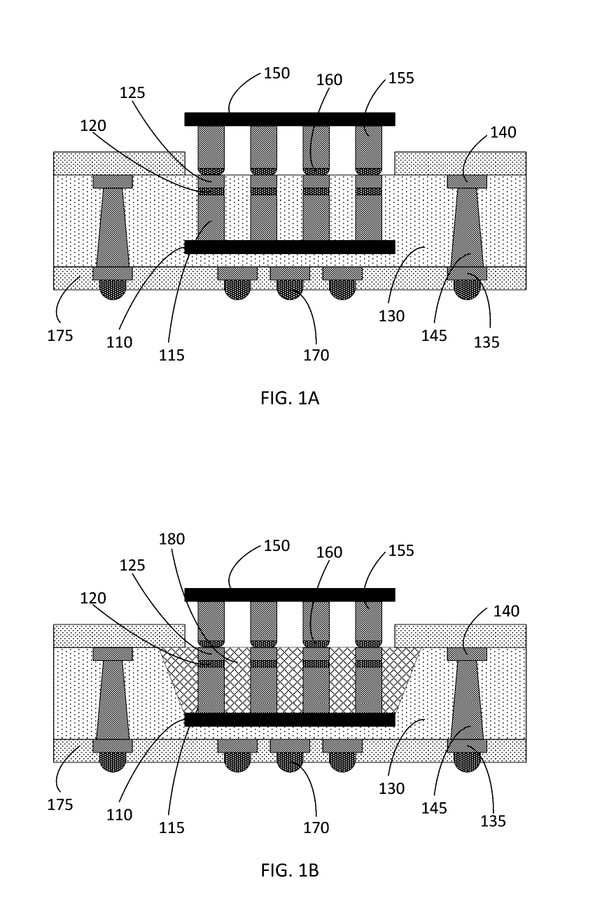

FIG. 1A illustrates an example embodiment of a semiconductor device according to an aspect of the disclosed subject matter. The semiconductor device in FIG. 1A may be formed through one or more methods that will be described in detail further below. The semiconductor device may include a substrate 130, which may be formed of an insulator and/or a dielectric material. The semiconductor device may also include a first die 110, first die bumps 115 (e.g. interconnects, pillars, copper pillars) and first joints 120 (e.g. solder joint or other material which allows the first die bumps 115 to be coupled to another conductor). The first die 110, which may comprise a logic circuit and/or a memory circuit or other type of die, may be embedded in the substrate 130. The first die bumps 115 may provide electrical connections to the first die 110—more specifically, may provide connections to the circuit of the first die 110. The first die bumps 115 may be formed from conductive materials such as copper. The first joints 120 may be coupled to the first die bumps 115.

The semiconductor device may include patterned contacts 125 formed on the first joints 120. The patterned contacts 125 may be coupled to the first joints 120 such that the first die 110 can be electrically coupled to the patterned contacts 125 through the first die bumps 115 and the first joints 120. The patterned contacts 125 may be at or below a height of the substrate 130. In FIG. 1A, the patterned contacts 125 are illustrated as being within the substrate 130 and coplanar with a top surface of the substrate 130, i.e., at the height of the substrate 130.

FIG. 1B illustrates another example embodiment of a semiconductor device according to an aspect of the disclosed subject matter. The semiconductor device of FIG. 1B is similar to that of FIG. 1A. However, the devices differ in the following respect. The device in FIG. 1B may include an underfill 180 disposed at least partially around the patterned contacts 125, the first die bumps 115, and the first joints 120. The device in FIG. 1B may be formed with an underfill process (e.g. the underfill 180) while the device in FIG. 1A may be formed without the underfill process.

As seen in both FIGS. 1A and 1B, the semiconductor device may optionally include a second die 150, second die bumps 155 and second joints 160. The second die 150 may comprise a logic circuit and/or a memory circuit. The second die bumps 155 may provide electrical connections to the second die 150—more specifically provide connections to the circuit of the second die 150. The second die bumps 155 may be formed from conductive materials such as copper.

The second joints 160, which may also be solder joints or other conductive material, may be coupled to the second die bumps 155 and to the patterned contacts 125. For example, the second joints 160 may be coupled to the second die bumps 155 on one side and coupled to the patterned contacts 125 on another side such that the first die 110 can be electrically coupled to the second die 150 through the first die bumps 115, the first joints 120, the patterned contacts 125, the second joints 160 and the second die bumps 155.

Unlike the first die 110, at least a portion of the second die 150 may be at or above the height of the substrate 130. In FIGS. 1A and 1B, the second die 150 in its entirety is illustrated as being above the substrate 130. When the patterned contacts 125 are coplanar with the top surface of the substrate 130, then the second die bumps 155 and second joints 160 may also be at or above the height of the substrate.

The semiconductor device may include resist layers 175 (e.g., solder resist layers) formed above and/or below the substrate 130. The device may also include one or more first conductive layers 135 formed at a first surface (e.g., lower surface) of the substrate 130 within the lower resist layer 175. The first conductive layers 135, which may represent traces, may be formed from conductive materials such as copper.

The semiconductor device may include one or more second conductive layers 140 formed within the substrate 130. In FIGS. 1A and 1B, the second conductive layers 140 are shown to be formed at a second surface (e.g., upper surface) of the substrate 130. That is, the second conductive layers 140 may be coplanar with the patterned contacts 125. While not shown in these figures, the second conductive layers 140 may represent traces. Some of these traces may electrically couple with the circuit of the first die 110 and/or the second die 150.

The semiconductor device may include one or more vias 145. Through-substrate vias (TSVs) are one examples of vias 145. The vias 145 may electrically couple the first conductive layers 135 to the second conductive layers 140. The vias 145 may be formed from a conductive material such as copper.

The semiconductor device may include one or more third bumps 170 coupled to the first conductive layers 135. The third bumps 170 may be formed as solder bumps. External access to the semiconductor device (e.g., to the first die 110 and/or the second die 150) may be provided through the third bumps 170. That is, electrical coupling of external devices with the first and/or second die 110, 150 may be provided through the third bumps 170, the first conductive layers 135, the vias 145 and the second conductive layers 140.

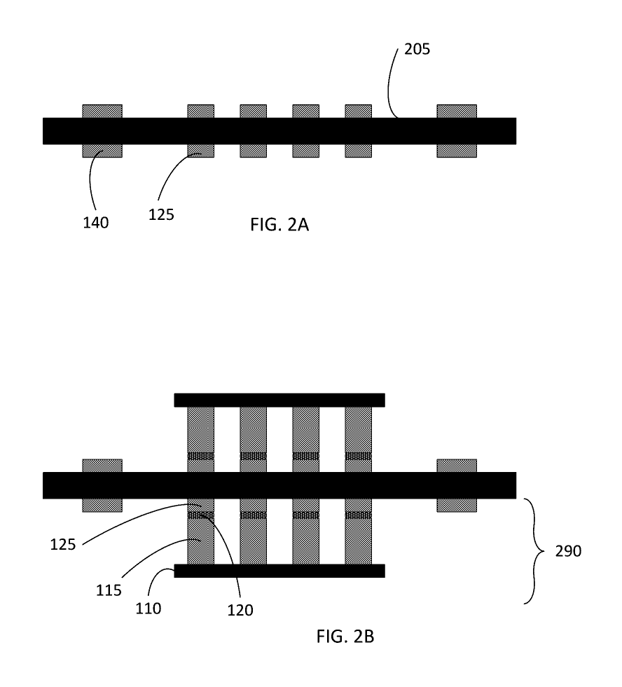

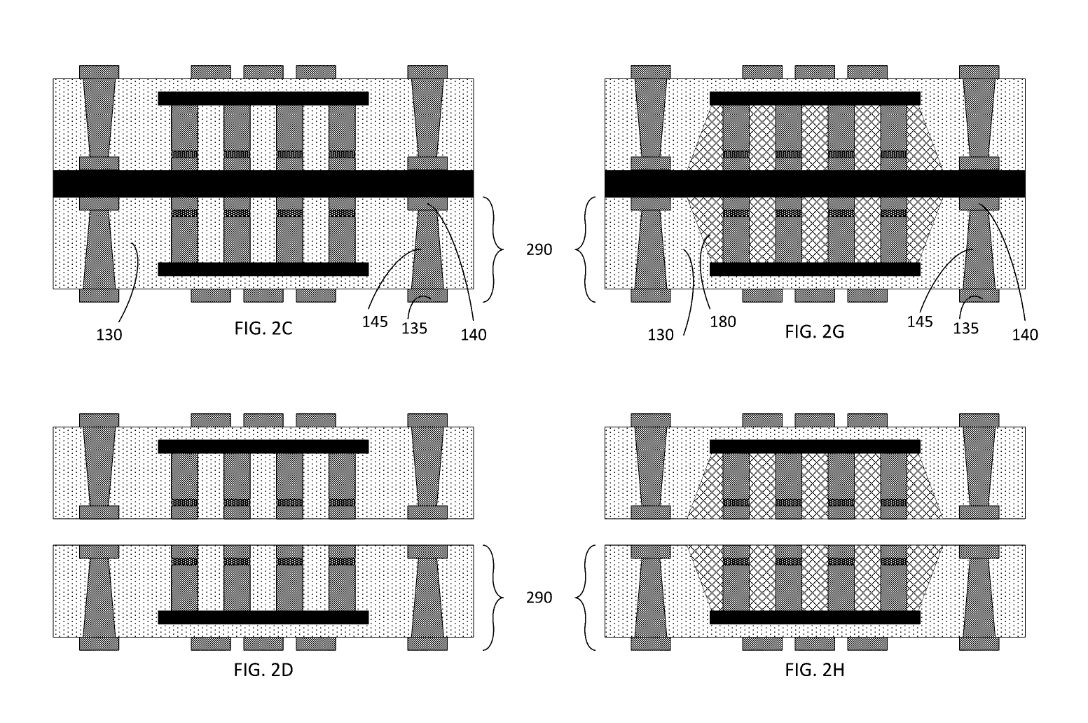

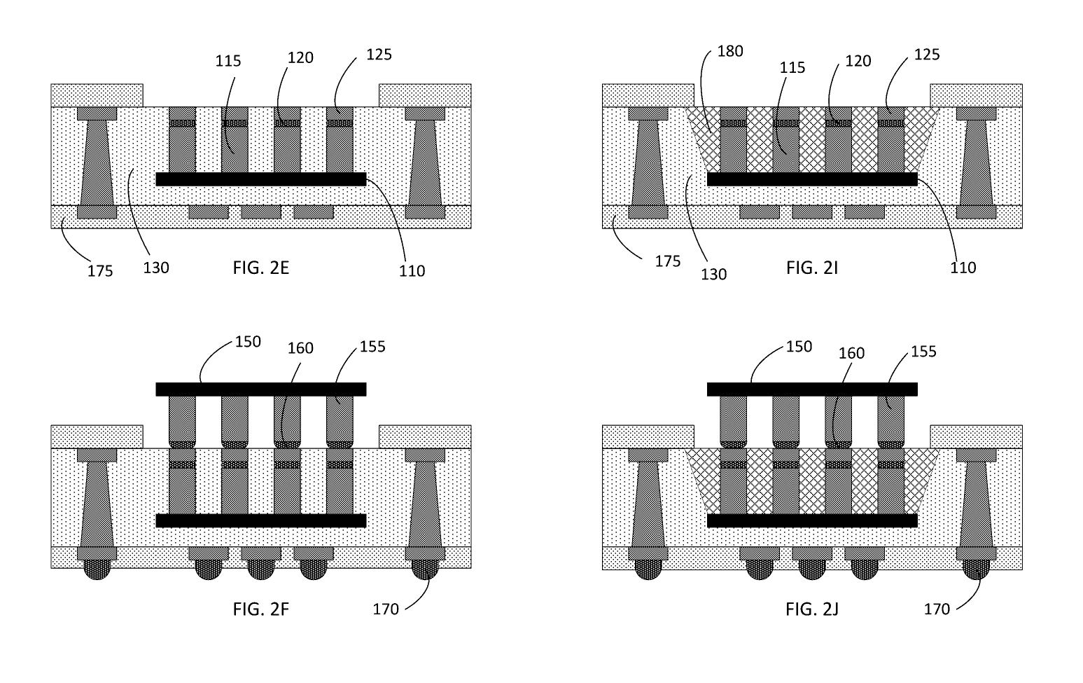

FIGS. 2A-2J illustrates different processing stages of forming a semiconductor device.

FIGS. 2A and 2B illustrate examples of stages common to forming the semiconductor devices of both FIGS. 1A and 1B. FIGS. 2C-2F illustrate examples of stages of forming the semiconductor device of FIG. 1A. FIGS. 2G-2J illustrate examples of stages of forming the semiconductor device of FIG. 1B.

As seen in these figures, there can be a carrier 205 on which a semiconductor device may be formed. In particular, a die assembly, which includes a die, can be formed on either side of the carrier 205. For convenience of description, the die assembly formed on a lower side of the carrier 205 will be described. The die assembly formed below the carrier 205 will be referred to as the first die assembly 290 and will be assumed to include the first die 110.

Note that a similar assembly may be formed an upper side the carrier 205 and can just as easily be used. Also, the two assemblies—above and below the carrier 205—may be formed together as illustrated in the figures. If the upper assembly is also formed, then much of the discussion related to the first die assembly 290 may apply to the upper assembly unless indicated otherwise. It should be noted that terms such as “upper” and “lower” are used for convenience, and should not be taken to refer to absolute directions unless indicated otherwise.

FIG. 2A illustrates a stage in forming a semiconductor device, and in particular a stage in forming the first die assembly 290. As seen, the patterned contacts 125 and the second conductive layers 140 may be formed on the carrier 205. In doing so, the patterned contacts 125 and the second conductive layer 140 can be made to be coplanar.

FIG. 2B illustrates a stage in forming the first die assembly 290 in which the first die 110, the first die bumps 115 and the first joints 120 may be formed. The first die bumps 115 may be formed to couple to the first die 110. Also, the first joints 120 may be formed to couple to the first die bumps 115 (e.g., on one side) and to the patterned contacts 125 (e.g., on another side). In this way, the first die 110 may be electrically coupled to the patterned contacts 125 through the first die bumps 115 and the first joints 120.

FIG. 2C illustrates a stage of forming the first die assembly 290 in which the substrate 130 may be provided. As seen, the substrate 130 may be provided so as to embed the first die 110 in the substrate 130. For example, the substrate 130 may be provided on the carrier 205 and grown (downwards in the figure) so as to partially or completely encapsulate the first die 110. The substrate 130 may also be provided such that the patterned contacts 125 are at or below the height of the substrate 130. In this particular example, the patterned contacts 125 and the substrate 130 are shown to be at the same height. In an embodiment, this can be accomplished without a polishing process since both the patterned contacts 125 and the substrate 130 can be formed on the carrier 205.

In an aspect, the substrate 130 may be provided after the first die 110, the first die bumps 115, the first joints 120, and the patterned contacts 125 are formed. That is, the stage illustrated in FIG. 2C can be subsequent to the stages illustrated in FIGS. 2A and 2B. By providing the substrate 130 subsequently, the first die 110 can be embedded in the substrate 130 without having to form a cavity.

FIG. 2C corresponds to a stage of forming the semiconductor device illustrated in FIG. 1A in which the substrate 130 may be disposed at least partially around the patterned contacts 125, the first die bumps 115, and the first joints 120. On the other hand, FIG. 2G corresponds to a stage of forming the semiconductor device illustrated in FIG. 1B in which the underfill 180 may be provided.

A stage of forming the first die assembly 290 may include providing the underfill 180 as seen in FIG. 2G. The underfill 180 may be provided so as to be disposed at least partially around the patterned contacts 125, the first die bumps 115, and the first joints 120. The underfill 180 may be provided as part of an underfill process. Note that the substrate 130 may still be provided so as to partially or wholly embed the first die 110.

In an aspect, the underfill 180 may be provided after the first die 110, the first die bumps 115, the first joints 120, and the patterned contacts 125 are formed, i.e., subsequent to stages of FIGS. 2A and 2B. Again, by providing the underfill 180 subsequently, the first die 110 can be embedded without the necessity of forming a cavity.

FIGS. 2C and 2G both illustrate that forming the first die assembly 290 may also include forming one or more first conductive layers 135 and one or more vias 145. The first conductive layers 135 may be formed at a first surface (e.g., lower surface) of the substrate 130. The second conductive layers 140 may be at a second surface (e.g., upper surface) of the substrate 130 such that the patterned contacts 125 are coplanar with the second conductive layers 140. The vias 145 may be formed to electrically couple the first and second conductive layers 135, 145. The first and second conductive layers 135, 140 as well as the vias 145 (e.g., TSVs) may be formed from conductive materials such as copper. Also, the first and second conductive layers 135, 140 may represent traces.

FIGS. 2D and 2H illustrate stages of forming the semiconductor device in which the first die assembly 290 may be separated from the carrier 205. FIGS. 2E and 2I illustrate stages of further processing of the first die assembly 290 that may be performed after the separation from the carrier 205. For example, etching and/or solder mask processes may be performed to form the resist layers 175 (e.g., solder resist layers) on the upper and/or the lower surface of the substrate 130.

FIGS. 2F and 2J illustrate package assembly stages to arrive at the semiconductor devices illustrated in FIGS. 1A and 1B. As seen in FIGS. 2F and 2J, forming the semiconductor device may include forming the second die 150, the second die bumps 155, and the second joints 160. The second die bumps 155 may be coupled to the second die 150. The second joints 160 may be coupled to the second die bumps 155 (e.g., on one side) and coupled to the patterned contacts 125 (e.g., on another side) such that the first die 110 can be electrically coupled to the second die 150 through the first die bumps 115, the first joints 120, the patterned contacts 125, the second joints 160 and the second die bumps 155. Also, at least a portion of the second die 150 may be above the height of the substrate 130. In addition, one or more third bumps 170 may be formed to couple to the first conductive layers 135.

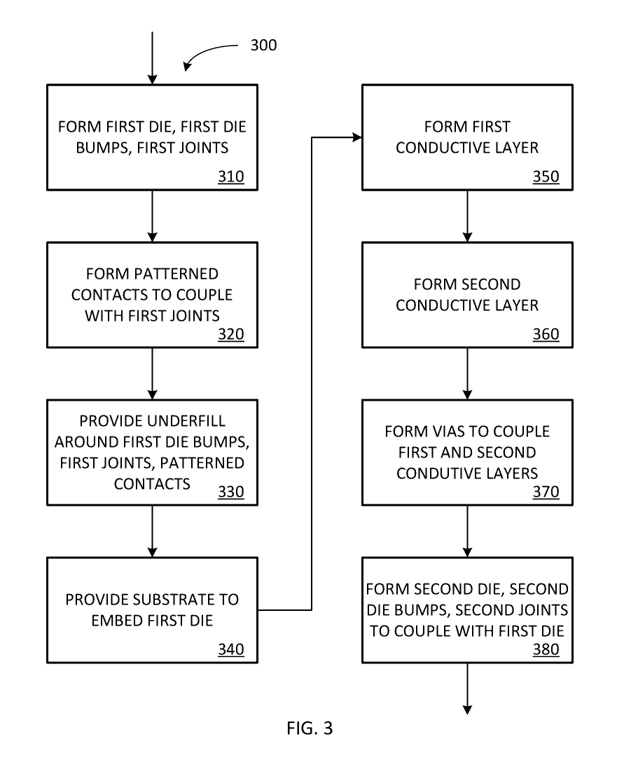

FIG. 3 illustrates a flow chart of an example method 300 of forming a semiconductor device such as the devices illustrated in FIGS. 1A and 1B. It should be noted that not all illustrated blocks of FIG. 3 need to be performed, i.e., some blocks may be optional. Also, the numerical references to the blocks of the FIG. 3 should not be taken as requiring that the blocks should be performed in a certain order.

In block 310, the first die 110, the first die bumps 115 and the first joints 120 may be formed. The first die bumps 115 may be coupled to the first die 110, and the first joints 120 may be coupled to the first die bumps 115. In block 320, the patterned contacts 125 may be formed to couple with the first joints 120. In this way, the first die 110 may be electrically coupled to the patterned contacts 125 through the first die bumps 115 and the first joints 120.

Optionally, in block 330, the underfill 180 may be provided. The underfill 180 may be disposed at least partially around the patterned contacts 125, the first die bumps 115, and the first joints 120. In an aspect, block 330 may be performed after blocks 310 and 320 are performed, i.e., the underfill 180 may be provided after the after the first die 110, the first die bumps 115, the first joints 120, and the patterned contacts 125 are formed. In this way, there is no need to form a cavity to embed the first die 110.

Regardless of whether block 330 is performed or not, the substrate 130 may be provided in block 340. In this block, the substrate 130 may be provided such that the first die 110 is embedded partially or completely in the substrate 130. The substrate 130 may also be provided such that the patterned contacts 125 are at or below a height of the substrate 130. In an aspect, block 340 may be performed after blocks 310 and 320 are performed. That is, the substrate 130 may be provided after the first die 110, the first die bumps 115, the first joints 120, and the patterned contacts 125 are formed. Again, this has the advantage that cavity forming can be eliminated.

In block 350, a first conductive layer 135 may be formed at a first surface of the substrate 130. In block 360, a second conductive layer 140 may be formed at a second surface of the substrate 130 such that the patterned contacts 125 are coplanar with the second conductive layer 140. In block 370, vias 145 may be formed to electrically couple the first conductive layer 135 with the second conductive layer 140.

Optionally, in block 380, the second die 150, the second die bumps 155, and the second joints 160 may be formed. The second die bumps 155 may be coupled to the second die 150. The second joints 160 may be coupled to the second die bumps 155 (e.g., on one side) and coupled to the patterned contacts 125 (e.g., on another side) such that the first die 110 can be electrically coupled to the second die 150 through the first die bumps 115, the first joints 120, the patterned contacts 125, the second joints 160 and the second die bumps 155.

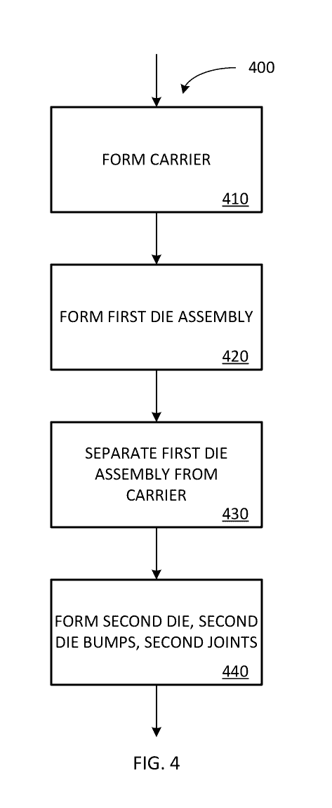

FIG. 4 illustrates a flow chart of another example method 400 of forming a semiconductor device. Again, some blocks may be optional. Also, the blocks need not be performed in numerical order unless specifically indicated. In block 410, a carrier 205 may be formed. FIG. 2A is illustrative of this block.

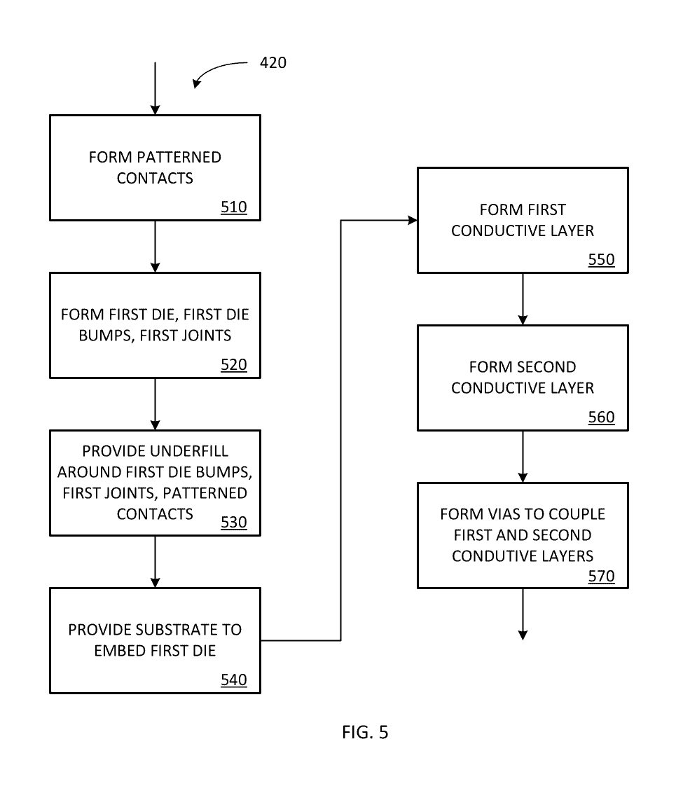

In block 420, the first die assembly 290 may be formed on the carrier 205. FIG. 5 illustrates a flow chart of an example process to implement block 420. In block 510, the patterned contacts 125 maybe formed on the carrier 205. FIG. 2A is also illustrative of this block. In block 520, the first die 110, the first die bumps 115 and the first joints 120 may be formed. FIG. 2B is illustrative of this block. As seen, the first die bumps 115 may be formed to be coupled to the first die 110. The first joints 120 may be formed to be coupled to the first die bumps 115 (e.g., on one side) and also coupled to the patterned contacts 125 (e.g., on another side) such that the first die 110 can be electrically coupled to the patterned contacts 125 through the first die bumps 115 and the first joints 120.

Optionally, in block 530, the underfill 180 may be provided so as to be disposed at least partially around the patterned contacts 125, the first die bumps 115 and the first joints 120. FIG. 2G is illustrative of this block. In an aspect, this block may be performed after blocks 510 and 520 are performed, i.e., the underfill 180 may be provided after the first die 110, the first die bumps 115, the first joints 120, and the patterned contacts 125 are formed.

In block 540, the substrate 130 may be provided such that the first die 110 is partially or completely embedded in the substrate 130. FIG. 2C is illustrative of this block. FIG. 2G is illustrative of this block when the underfill 180 is provided. In an aspect, block 540 may be performed after blocks 510 and 520 are performed, i.e., the substrate 130 may be provided after the first die 110, the first die bumps 115, the first joints 120, and the patterned contacts 125 are formed.

In block 550, the first conductive layers 135 may be formed at a first surface of the substrate 130. In block 560, the second conductive layers 140 may be formed on the carrier 205. In an aspect, blocks 510 and 560 may be performed contemporaneously, i.e., the patterned contacts 125 and the second conductive layers 140 may be formed together (e.g., see FIG. 2A). In this way, the second conductive layers 140 may be formed at a second surface of the substrate 130 and coplanar with the second conductive layers 140. In block 570, the vias 145 may be formed to electrically couple the first conductive layers 135 with the second conductive layers 140. FIGS. 2C and 2G are illustrative of these blocks.

Returning to FIG. 4, the first die assembly 290 may be separated from the carrier 205 in block 430. FIGS. 2D and 2H are illustrative of this block. The separated first die assembly 290 may undergo additional processing (e.g., etching, solder mask processing) as illustrated in FIGS. 2E and 2I.

Optionally, in block 440, the second die 150, the second die bumps 155 and the second joints 160 may be formed. FIGS. 2F and 2J are illustrative of this block. As seen, the second die bumps 160 may be formed to couple to the second die 150. Also, the second joints 160 may be formed to couple to the second die bumps 155 (e.g., on one side) and couple to the patterned contacts 125 (e.g., on another side). In this way, the first die 110 may be electrically coupled to the second die 150 through the first die bumps 115, the first joints 120, the patterned contacts 125, the second joints 160 and the second die bumps 155. Note that at least a portion of the second die 150 may be above the height of the substrate 130.

In an aspect, block 440 may be performed after block 430. That is, the second die 150, the second die bumps 155 and the second joints 160 may be formed after the first die assembly 290 has been separated from the carrier 205. In particular, the second die 150, the second die bumps 155 and the second joints 160 may be formed after the first die 110, the first die bumps 115, the first joints 120, and the patterned contacts 125 have been formed and separated from the carrier 205.

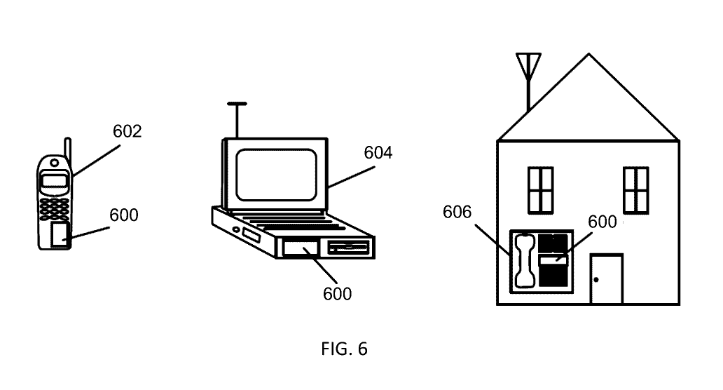

FIG. 6 illustrates various electronic devices that may be integrated with any of the aforementioned semiconductor device. For example, a mobile phone device 602, a laptop computer device 604, and a fixed location terminal device 606 may include a semiconductor device 600 as described herein. The semiconductor device 600 may be, for example, any of the integrated circuits, dies, integrated devices, integrated device packages, integrated circuit devices, device packages, integrated circuit (IC) packages, package-on-package devices described herein. The devices 602, 604, 606 illustrated in FIG. 6 are merely exemplary. Other electronic devices may also feature the semiconductor device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the embodiments disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present d.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment can include a computer readable media embodying a method of forming a semiconductor device. Accordingly, the scope of the disclosed subject matter is not limited to illustrated examples and any means for performing the functionality described herein are included.

While the foregoing disclosure shows illustrative embodiments, it should be noted that various changes and modifications could be made herein without departing from the scope of the disclosed subject matter as defined by the appended claims. The functions, processes and/or actions of the method claims in accordance with the embodiments of the disclosed subject matter described herein need not be performed in any particular order. Furthermore, although elements of the disclosed subject matter may be described or claimed in the singular, the plural is contemplated unless limitation to the singular is explicitly stated.

1. A semiconductor device, comprising:
a substrate;
a first die embedded in the substrate;
first die bumps coupled to the first die;
first joints coupled to the first die bumps; and
patterned contacts coupled to the first joints such that the first die is electrically coupled to the patterned contacts through the first die bumps and the first joints,
wherein the patterned contacts are at or below a height of the substrate.

2. The semiconductor device of claim 1, further comprising:
a second die;
second die bumps coupled to the second die; and
second joints coupled to the second die bumps and coupled to the patterned contacts such that the first die is electrically coupled to the second die through the first die bumps, the first joints, the patterned contacts, the second joints and the second die bumps.

3. The semiconductor device of claim 2, wherein at least a portion of the second die is above the height of the substrate.

4. The semiconductor device of claim 1, further comprising:
an underfill disposed at least partially around the patterned contacts, the first die bumps, and the first joints.

5. The semiconductor device of claim 1, further comprising:
a first conductive layer at a first surface of the substrate; and
a second conductive layer at a second surface of the substrate,
wherein the patterned contacts are coplanar with the second conductive layer.

6. The semiconductor device of claim 5, further comprising:
vias in the substrate electrically coupling the first conductive layer to the second conductive layer.

7. The semiconductor device of claim 1, wherein the semiconductor device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

8. A method of forming a semiconductor device, the method comprising:
forming a first die;
forming first die bumps and coupling the first die bumps to the first die;
forming first joints and coupling the first joints to the first die bumps;
forming patterned contacts and coupling the patterned contacts to the first joints such that the first die is electrically coupled to the patterned contacts through the first die bumps and the first joints; and
providing a substrate such that the first die is embedded in the substrate and such that the patterned contacts are at or below a height of the substrate.

9. The method of claim 8, wherein the substrate is provided after the first die, the first die bumps, the first joints, and the patterned contacts are formed.

10. The method of claim 8, further comprising:
forming a second die;
forming second die bumps and coupling the second die bumps to the second die; and
forming second joints and coupling the second joints to the second die bumps and to the patterned contacts such that the first die is electrically coupled to the second die through the first die bumps, the first joints, the patterned contacts, the second joints and the second die bumps.

11. The method of claim 10, wherein at least a portion of the second die is above the height of the substrate.

12. The method of claim 8, further comprising:
providing an underfill so as to be disposed at least partially around the patterned contacts, the first die bumps, and the first joints.

13. The method of claim 12, wherein the underfill is provided after the first die, the first die bumps, the first joints, and the patterned contacts are formed.

14. The method of claim 8, further comprising:
forming a first conductive layer at a first surface of the substrate; and
forming a second conductive layer at a second surface of the substrate such that the patterned contacts are coplanar with the second conductive layer.

15. The method of claim 14, further comprising:
forming vias to electrically couple the first conductive layer to the second conductive layer.

16. A method of forming a semiconductor device, the method comprising:
forming a carrier;
forming a first die assembly on the carrier; and
separating the first die assembly from the carrier,
wherein forming the first die assembly comprises:
forming patterned contacts on the carrier;
forming a first die;
forming first die bumps and coupling the first die bumps to the first die;
forming first joints and coupling the first joints to the first die bumps and to the patterned contacts such that the first die is electrically coupled to the patterned contacts through the first die bumps and the first joints; and
providing a substrate such that the first die is embedded in the substrate and such that the patterned contacts are at or below a height of the substrate.

17. The method of claim 16, wherein the substrate is provided after the first die, the first die bumps, the first joints, and the patterned contacts are formed.

18. The method of claim 16, further comprising:
forming a second die;
forming second die bumps and coupling the second die bumps to the second die; and
forming second joints and coupling the second joints to the second die bumps and to the patterned contacts such that the first die is electrically coupled to the second die through the first die bumps, the first joints, the patterned contacts, the second joints and the second die bumps.

19. The method of claim 18, wherein the second die is formed such that at least a portion of the second die is above the height of the substrate.

20. The method of claim 18, wherein the second die, the second die bumps, and the second joints are formed after the first die assembly is separated from the carrier.

21. The method of claim 16, wherein forming the first die assembly further comprises:
providing an underfill so as to be disposed at least partially around the patterned contacts, the first die bumps, and the first joints.

22. The method of claim 21, wherein the underfill is provided after the first die, the first die bumps, the first joints, and the patterned contacts are formed.

23. The method of claim 16, wherein forming the first die assembly further comprises:
forming a first conductive layer at a first surface of the substrate; and
forming a second conductive layer at a second surface of the substrate such that the patterned contacts are coplanar with the second conductive layer.

24. The method of claim 23, wherein forming the first die assembly further comprises:
forming vias to electrically couple the first conductive layer to the second conductive layer.
